(19) United States
(12) Patent Application Publication
(10) Pub. No.: US 2010/0109755 A1
(43) Pub. Date: May 6, 2010

(54) SEMICONDUCTOR DEVICE

(75) Inventors: Hiroshi Kumano, Kyoto (JP); Eiji Nakagawa, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-shi (JP)

(21) Appl. No.: 12/595,596

(22) PCT Filed: Apr. 11, 2008
(86) PCT No.: PCT/JP2008/057166

§ 371 Date: Dec. 31, 2009

(30) Foreign Application Priority Data
Apr. 12, 2007 (JP) 2007-105213

(51) Int. Cl. H03K 3/01

(52) U.S. Cl. 327/534

(57) ABSTRACT

A semiconductor device capable of improving the breakdown voltage in the overall device is provided. The semiconductor device includes: a semiconductor substrate; a p-MOS formed on a surface layer portion of the semiconductor substrate; an n-MOS formed on the surface layer portion of the semiconductor substrate and serially connected with the p-MOS between a power source and a ground; and a substrate potential control circuit for controlling the potential of the back surface of the semiconductor substrate to an intermediate potential higher than the ground potential and lower than the potential of the power source.

### TECHNICAL FIELD

The present invention relates to a semiconductor device mixedly provided with a p-MOS (a p-channel MOS transistor) and an n-MOS (an n-channel MOS transistor), and more particularly, it relates to a semiconductor device having a p-MOS and an n-MOS mixedly provided on an SOI (Silicon On Insulator) substrate.

### PRIOR ART

A complete dielectric isolation technique is used for a semiconductor device such as an IC for PDP (Plasma Display Panel) Driver or an IC for Automotive Electronics.

Such a semiconductor device has a structure in which a deep trench deeply dug from the surface of an SOI substrate is formed in a surface layer portion (a silicon layer) of the SOI substrate and a p-MOS and an n-MOS are isolated (DTI: Deep Trench Isolation) from each other by the deep trench, for example. Patent Document 1: Japanese Unexamined Patent Publication No. 2006-5375

### DISCLOSURE OF THE INVENTION

### Problems to be Solved

An object of the present invention is to provide a semiconductor device to regulate a p-MOS and an n-MOS breakdown voltages respectively so that the breakdown voltage in the overall device is improved.

### Solutions to the Problems

A semiconductor device according to an aspect of the present invention includes: a semiconductor substrate; a p-MOS formed on a surface layer portion of the semiconductor substrate; an n-MOS formed on the surface layer portion of the semiconductor substrate and serially connected with the p-MOS between a power source and a ground; and a substrate potential control circuit for controlling the potential of the back surface of the semiconductor substrate to an intermediate potential higher than the ground potential and lower than the potential of the power source.

The p-MOS and the n-MOS on the semiconductor substrate have different breakdown voltage characteristics respectively. It is generally known that the breakdown voltage characteristics of the p-MOS and the n-MOS depend on the potential (the substrate potential) of the back surface of the semiconductor substrate. In other words, the p-MOS has such characteristics that the breakdown voltage is low when the substrate potential is low and the breakdown voltage is high when the substrate potential is high, as shown in FIG. 7. On the other hand, the n-MOS has such characteristics that the breakdown voltage is high when the substrate potential is low and the element breakdown voltage is low when the substrate potential is high.

When a substrate potential is set to the ground potential in a semiconductor device (a semiconductor chip) in which a p-MOS and an n-MOS are mixedly provided on a common semiconductor substrate, therefore, the breakdown voltage (the maximum voltage at which no breakdown is caused in the p-MOS and the n-MOS on the semiconductor device) in the overall semiconductor device corresponds to the breakdown voltage of the p-MOS. When the substrate potential is set to a high-voltage power supply potential, the breakdown voltage in the overall semiconductor device corresponds to the breakdown voltage of the n-MOS. In other words, the breakdown voltage in the overall semiconductor device does not exceed the breakdown voltage of the p-MOS in the case of setting the substrate potential to the ground potential or the breakdown voltage of the n-MOS in the case of setting the substrate potential to the high-voltage power supply potential.

In the semiconductor device according to the aspect of the present invention, the potential (the substrate potential) of the back surface of the semiconductor substrate mixedly provided with the p-MOS and the n-MOS is controlled to the intermediate potential between the ground potential and the potential (the power supply potential) of the power source. Thus, the breakdown voltage of the p-MOS can be increased as compared with a case of setting the potential of the semiconductor substrate to the ground potential. Further, the breakdown voltage of the n-MOS can be increased as compared with a case of setting the substrate potential to the power supply potential. Consequently, the breakdown voltage in the overall device can be improved as compared with a conventional semiconductor device.

The source of the p-MOS maybe connected to the power source, the source of the n-MOS may be connected to the ground, and the drain of the p-MOS and the drain of the n-MOS may be connected with each other.

The substrate potential control circuit may include a resistor having an end connected to the power source and another end connected to the ground, and a connecting wire for electrically connecting an intermediate portion of the resistor and the back surface of the semiconductor substrate with each other.

According to the structure, the end of the resistor is connected to the power source and the other end thereof is earthed (connected to the ground), whereby the substrate potential can be set to the intermediate potential between the ground potential and the power supply potential by connecting the intermediate portion of the resistor and the back surface of the semiconductor substrate with each other by the connecting wire.

The substrate potential (the potential of the intermediate portion to which the connecting wire is connected) depends on the ratio between the resistance value from the end of the resistor to the intermediate portion to which the connecting wire is connected and the resistance value from the intermediate portion to the other end of the resistor. Therefore, the substrate potential can be set to such a potential that the breakdown voltage of the p-MOS and the breakdown voltage of the n-MOS match with each other by properly setting the position (the position of the intermediate portion) of the resistor to which the connecting wire is connected. Thus, the breakdown voltage in the overall device can be further improved.

The substrate potential control circuit may include a self-feedback p-MOS formed on the semiconductor substrate with a gate and a source connected to the power source and a drain connected to a voltage output terminal, a self-feedback n-MOS formed on the semiconductor substrate with a gate and a source connected to the ground and a drain connected to the voltage output terminal, and a connecting wire for electrically connecting the voltage output terminal and the back surface of the semiconductor substrate with each other.

The breakdown voltage of the self-feedback p-MOS is lower than the breakdown voltage of the p-MOS at the same substrate potential. The breakdown voltage of the self-feedback n-MOS is lower than the breakdown voltage of the n-MOS at the same substrate potential.

According to the structure, the potential of the voltage output terminal shifts toward the power supply potential side and the substrate potential shifts toward the power supply potential side when a leakage current responsive to secondary breakdown is generated in the self-feedback p-MOS. When the substrate potential shifts toward the power supply potential side, the breakdown voltage of the p-MOS rises, whereby occurrence of breakdown in the p-MOS can be prevented. When the substrate potential shifts toward the power supply potential side, on the other hand, the breakdown voltages of the n-MOS and the self-feedback n-MOS lower. However, a leakage current responsive to secondary breakdown is generated in the self-feedback n-MOS before occurrence of breakdown in the n-MOS, whereby the potential of the voltage output terminal shifts toward the ground side, and the substrate potential shifts toward the ground side. Consequently, the breakdown voltage of the n-MOS rises, whereby occurrence of breakdown in the n-MOS can be prevented. Therefore, the breakdown voltage in the overall device can be further improved.

In addition, the substrate potential control circuit consisting of the self-feedback p-MOS and the self-feedback n-MOS has a small circuit area, whereby the same has such an advantage that upsizing of the semiconductor device can be avoided. The substrate potential control circuit also has such an advantage that current consumption is small.

The foregoing and other objects, features and effects of the present invention will become more apparent from the following detailed description of the embodiments with reference to the attached drawings.

### BRIEF DESCRIPTION OF THE DRAWINGS

FIG. 1 is a sectional view schematically showing the structure of a semiconductor device according to an embodiment of the present invention.

FIG. 2 is a circuit diagram of a PDP scan driver circuit provided in the semiconductor device shown in FIG. 1.

FIG. 3 is a schematic plan view of a resistive divider circuit provided in the semiconductor device shown in FIG. 1.

FIG. 4 is a circuit diagram of the resistive divider circuit shown in FIG. 3.

FIG. 5 is a schematic plan view showing another structure of a semiconductor chip (the semiconductor device).

FIG. 6 is a circuit diagram of a self-feedback circuit shown in FIG. 5.

FIG. 7 is a graph showing substrate potential dependency of the breakdown voltages of a p-MOS and an n-MOS.

### DESCRIPTION OF THE REFERENCE NUMERALS

1 semiconductor device

2 semiconductor chip

6 connecting wire

14 p-MOS

15 p-MOS

16 n-MOS

17 n-MOS

20 p-MOS

21 n-MOS

30 resistive divider circuit (substrate potential control circuit)

31 SOI substrate (semiconductor substrate)

32 resistor

40 self-feedback circuit (substrate potential control circuit)

41 p-MOS (self-feedback p-channel MOS transistor)

42 n-MOS (self-feedback n-channel MOS transistor)

44 voltage output terminal

GND ground

VDD high-voltage power source

### BEST MODE FOR CARRYING OUT THE INVENTION

An embodiment of the present invention is now described in detail with reference to the attached drawings.

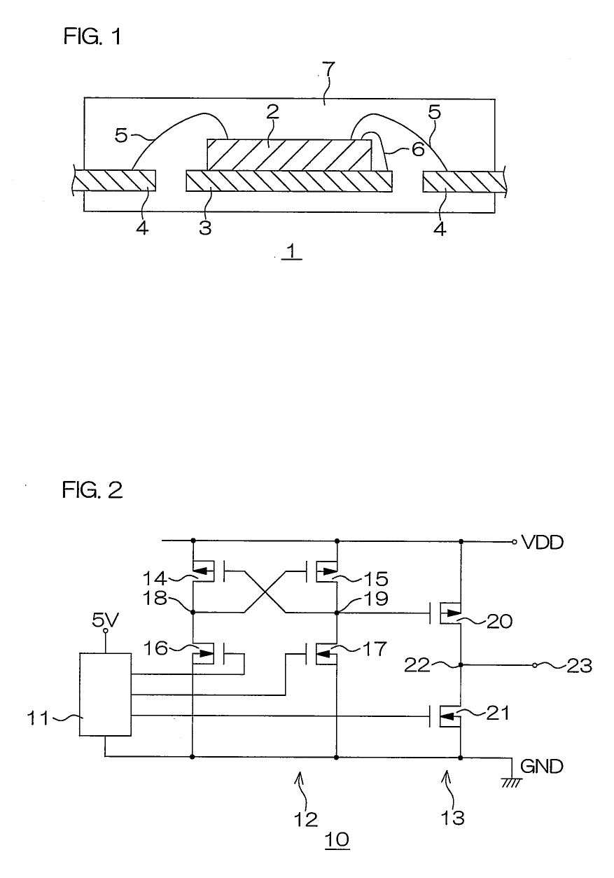

FIG. 1 is a sectional view schematically showing the structure of a semiconductor device according to the embodiment of the present invention.

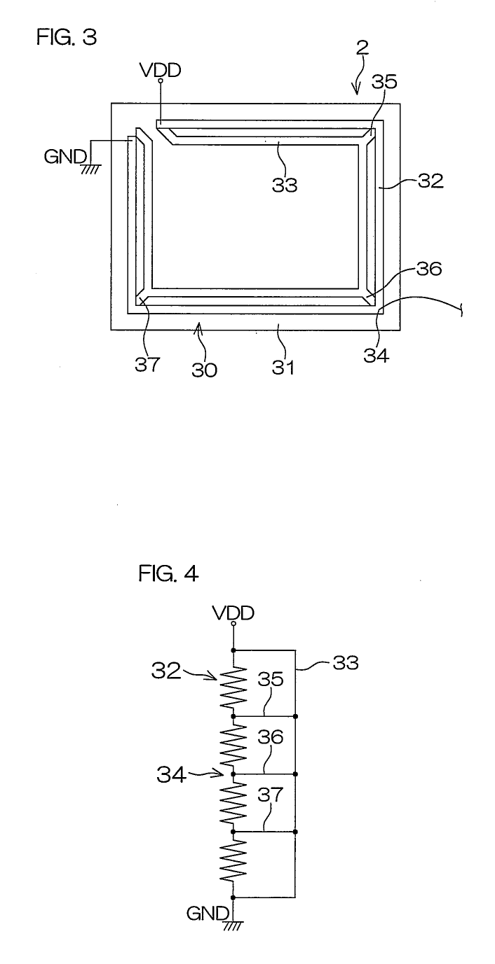

A semiconductor device 1 includes a semiconductor chip 2 based on an SOI substrate 31 (see FIG. 3), for example. A PDP scan driver circuit 10 described later, for example, is formed on a surface layer portion (a silicon layer) of the SOI substrate 31. A resistive divider circuit 30 described later is formed on the surface of the SOI substrate 31. A plurality of main pads (not shown) for electrical connection with the PDP scan driver circuit 10 and three substrate potential control pads (not shown) for electrical connection with the resistive divider circuit 30 are arranged on the outermost surface of the semiconductor chip 2.

The semiconductor chip 2 is die-bonded to a die pad 3. A plurality of leads 4 are alignedly provided on the periphery of the die pad 3. The main pads on the surface of the semiconductor chip 2 are electrically connected with the leads 4 through bonding wires 5. Two of the substrate potential control pads on the surface of the semiconductor chip 2 are electrically connected with the leads 4 through the bonding wires 5, and the remaining substrate potential control pad is connected with the die pad 3 through a connecting wire 6.

The semiconductor chip 2 is sealed with a resin package 7 along with the die pad 3, the leads 4, the bonding wires 5 and the connecting wire 6. The leads 4 are partially exposed from the resin package 7, to function as external joints (outer lead portions) for connection with a printed wiring board.

FIG. 2 is a circuit diagram of the PDP scan driver circuit.

The PDP scan driver circuit 10 includes a low voltage signal circuit 11, a level shift circuit 12 and an output circuit 13.

The low voltage signal circuit 11 operates with an operating voltage of 5 V, and outputs signals IN1, IN2 and IN3. The signals IN1 and IN3 switch between Hi (high levels) and Lo (low levels) in phase with each other, while the signal IN2 switches between Hi and Lo out of phase with the signals IN1 and IN3.

The level shift circuit 12 includes two p-MOSes 14 and 15 and two n-MOSes 16 and 17. The sources of the p-MOSes 14 and 15 are connected to a high-voltage power source VDD through the corresponding main pads arranged on the outermost surface of the semiconductor chip 2 (see FIG. 1). The sources of the n-MOSes 16 and 17 are connected (earthed) to a ground GND through the corresponding main pads. The drain of the p-MOS 14 and the drain of the n-MOS 16 are connected with each other at a node 18. The drain of the p-MOS 15 and the drain of the n-MOS 17 are connected with each other at a node 19. The gate of the p-MOS 14 is connected to the node 19 between the p-MOS 15 and the n-MOS 17. The gate of the p-MOS 15 is connected to the node 18 between the p-MOS 14 and the n-MOS 16.

The output circuit 13 includes a p-MOS 20 and an n-MOS 21. The source of the p-MOS 20 is connected to the high-voltage power source VDD through the corresponding main pad. The source of the n-MOS 21 is connected to the ground GND through the corresponding main pad. The drain of the p-MOS 20 and the drain of the n-MOS 21 are connected with each other at a node 22. The node 22 is connected to an output terminal 23. The gate of the p-MOS 20 is connected to the node 19 between the p-MOS 15 and the n-MOS 17.

The signal IN1 from the low-voltage signal circuit 11 is input in the gate of the n-MOS 16 of the level shift circuit 12. The signal IN2 from the low-voltage signal circuit 11 is input in the gate of the n-MOS 17 of the level shift circuit 12. The signal IN3 from the low-voltage signal circuit 11 is input in the gate of the n-MOS 21 of the output circuit 13.

When the signal IN1 input in the gate of the n-MOS 16 and the signal IN3 input in the gate of the n-MOS 21 switch from Lo to Hi and the signal IN2 input in the gate of the n-MOS 17 switches from Hi to Lo at the same time, the n-MOS 16 and the n-MOS 21 are turned on, while the n-MOS 17 is turned off. When the n-MOS 16 is turned on, the potential of the node 18 reaches the ground potential (0 V), and the p-MOS 15 is turned on. When the p-MOS 15 is turned on, the potential of the node 19 reaches a high-voltage power supply potential (200 V, for example), and the p-MOS 20 is turned off. Consequently, the potential of the node 22 reaches the ground potential, and a low-level signal is output from the output terminal 23.

When the signal IN1 input in the gate of the n-MOS 16 and the signal IN3 input in the gate of the n-MOS 21 switch from Hi to Lo and the signal IN2 input in the gate of the n-MOS 17 switches from Lo to Hi at the same time, on the other hand, the n-MOS 16 and the n-MOS 21 are turned off, while the n-MOS 17 is turned on. When the n-MOS 17 is turned on, the potential of the node 19 reaches the ground potential, and the p-MOS 14 is turned on. When the p-MOS 14 is turned on, the potential of the node 18 reaches the high-voltage power supply potential, and the p-MOS 15 is turned off. When the potential of the node 19 reaches the ground potential, the p-MOS 20 is turned on. Consequently, the potential of the node 22 reaches the high-voltage power supply potential, and a high-level signal is output from the output terminal 23.

FIG. 3 is a schematic plan view of the resistive divider circuit. FIG. 4 is a circuit diagram of the resistive divider circuit shown in FIG. 3.

The resistive divider circuit 30 is formed on the surface of the rectangular SOI substrate 31 along the peripheral edge thereof. The resistive divider circuit 30 includes a resistor 32 made of a high-resistance conductive material (polysilicon, for example) and a short-circuit wire 33 made of a low-resistance conductive material (a material such as Au, Cu or Al, for example, generally used for a bonding wire).

An end of the resistor 32 is arranged in the vicinity of a corner portion of the SOI substrate 31 and extends along the peripheral edge of the SOI substrate 31 while another end thereof is arranged in the vicinity of the corner portion where the end is arranged, in plan view. The end of the resistor 32 is connected to the high-voltage power source VDD through the corresponding substrate potential control pad arranged on the outermost surface of the semiconductor chip 2 (see FIG. 1). The other end of the resistor 32 is connected to the ground GND through the corresponding substrate potential control pad. An intermediate portion 34 of the resistor 32 is electrically connected with the corresponding substrate potential control pad, and electrically connected with the back surface of the SOI substrate 31 through the connecting wire 6 connected with the substrate potential control pad and the die pad 3. Therefore, the potential (the substrate potential) of the back surface of the SOI substrate 31 is identical to the potential of the intermediate portion 34 of the resistor 32.

The short-circuit wire 33 is arranged inside the resistor 32, in parallel with the resistor 32. An end of the short-circuit wire 33 is connected to the end of the resistor 32. Another end of the short-circuit wire 33 is connected to the other end of the resistor 32. Further, the short-circuit wire 33 is connected to three intermediate portions of the resistor 32 through joints 35, 36 and 37 respectively. The joints 35, 36 and 37 are connected to respective positions generally the resistor 32 generally into quarters.

The potential of the intermediate portion 34 of the resistor 32 can be changed by cutting the short-circuit wire 33. In other words, the potential of the intermediate portion 34 of the resistor 32 can be set to generally 1/2 of the high-voltage power supply potential by cutting the short-circuit wire 33 between the end of the short-circuit wire 33 and the joint 35, between the joint 35 and the joint 36, between the joint 36 and the joint 37 and between the joint 37 and the other end of the short-circuit wire 33 respectively. Further, the potential of the intermediate portion 34 of the resistor 32 can be set to generally ⅔ of the high-voltage power supply potential by cutting the short-circuit wire 33 only between the joint 35 and the joint 36. In addition, the potential of the intermediate portion 34 of the resistor 32 can be set to generally ⅓ of the high-voltage power supply potential by cutting the short-circuit wire 33 only between the joint 36 and the joint 37.

The short-circuit wire 33 is cut on at least one portion. Thus, the potential of the intermediate portion 34 of the resistor 32 is set to an intermediate potential between the ground potential and the high-voltage power supply potential. In the semiconductor device 1, therefore, the substrate potential identical to the potential of the intermediate portion 34 is controlled to the intermediate potential between the ground potential and the high-voltage power supply potential. Thus, the breakdown voltages of the p-MOSes 14, 15 and 20 included in the PDP scan driver circuit 10 can be increased as compared with a case of setting the substrate potential to the ground potential. Further, the breakdown voltages of the n-MOSes 16, 17 and 21 included in the PDP scan driver circuit 10 can be increased as compared with a case of setting the substrate potential to the power supply potential. Consequently, the breakdown voltage in the overall device can be improved as compared with a conventional semiconductor device.

Further, the breakdown voltage in the overall device can be further improved by properly cutting the short-circuit wire 33 for setting the substrate potential so that the breakdown voltages of the p-MOSes 14, 15 and 20 and the breakdown voltages of the n-MOSes 16, 17 and 21 match with one another.

Moreover, the resistive divider circuit 30 is formed on the peripheral edge of the SOI substrate 31. Thus, increase in the size of the semiconductor chip 2 resulting from the provision of the resistive divider circuit 30 can be avoided. However, the resistive divider circuit 30 may not necessarily be formed on the peripheral edge of the SOI substrate 31, but increase in the size of the semiconductor chip 2 resulting from the provision of the resistive divider circuit 30 can be avoided if there is an empty space (a space where no elements or the like are formed) in a portion other than the peripheral edge of the SOI substrate 31, by forming the resistive divider circuit 30 in the empty space.

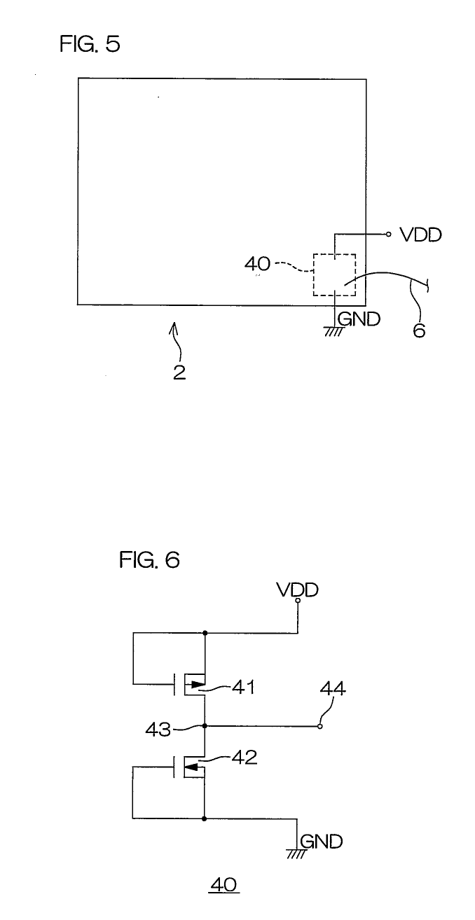

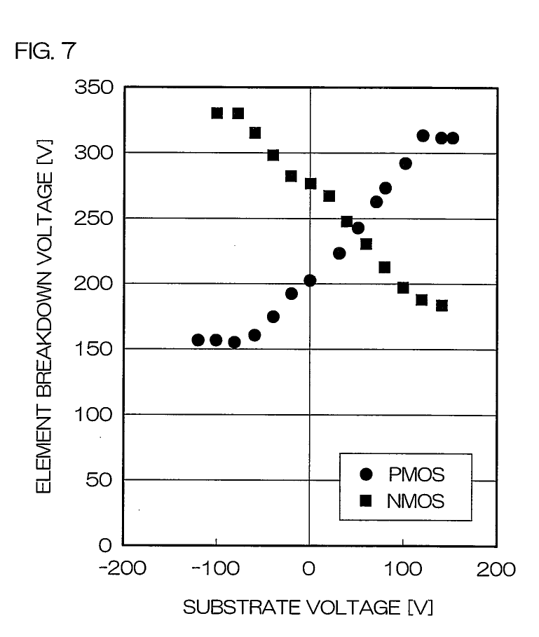

FIG. 5 is a schematic plan view showing another structure of the semiconductor chip.

In this semiconductor chip 2, a self-feedback circuit 40 for controlling the substrate potential in a self-feedback manner is formed on the surface layer portion (the silicon layer) of the SOI substrate 31 forming the base of the semiconductor chip 2, in place of the resistive divider circuit 30.

Three substrate potential control pads (not shown) for electrical connection with the self-feedback circuit 40 are arranged on the outermost surface of the semiconductor chip 2. Two of the substrate potential control pads are electrically connected with the leads 4 (see FIG. 1) through the bonding wires 5 (see FIG. 1), while the remaining substrate potential control pad is electrically connected with the die pad 3 (see FIG. 1) through the connecting wire 6.

FIG. 6 is a circuit diagram of the self-feedback circuit shown in FIG. 5.

The self-feedback circuit 40 includes a p-MOS 41 and an n-MOS 42. The gate and the source of the p-MOS 41 are connected to the high-voltage power source VDD through the corresponding substrate potential control pad. The gate and the source of the n-MOS 42 are connected to the ground GND through the corresponding substrate potential control pad. The drain of the p-MOS 41 and the drain of the n-MOS 42 are connected with each other at a node 43. The node 43 is connected to a voltage output terminal 44.

The voltage output terminal 44 is electrically connected to the corresponding substrate potential control pad, and electrically connected with the back surface of the SOI substrate 31 through the connecting wire 6 connected to the substrate potential control pad and the die pad 3. Therefore, the potential (the substrate potential) of the back surface of the SOI substrate 31 is controlled to be identical to the potential of the voltage output terminal 44.

According to the structure, the potential of the voltage output terminal 44 shifts toward the power supply potential side and the substrate potential shifts toward the power supply potential side when a leakage current responsive to secondary breakdown is generated in the p-MOS 41 of the self-feedback circuit 40. When the substrate potential shifts toward the power supply potential side, the breakdown voltages of the p-MOSes 14, 15 and 20 of the PDP scan driver circuit 10 rise, whereby occurrence of breakdown in the p-MOSes 14, 15 and 20 can be prevented. When the substrate potential shifts toward the power supply potential side, on the other hand, the breakdown voltages of the n-MOSes 16, 17 and 21 of the PDP scan driver circuit 10 and the n-MOS 42 of the self-feedback circuit 40 lower. However, a leakage current responsive to secondary breakdown is generated in the n-MOS 42 before occurrence of breakdown in the n-MOSes 16, 17 and 21, whereby the potential of the voltage output terminal shifts toward the ground side, and the substrate potential shifts toward the ground side. Consequently, the breakdown voltages of the n-MOSes 16, 17 and 21 rise, whereby occurrence of breakdown in the n-MOSes 16, 17 and 21 can be prevented. Therefore, the breakdown voltage in the overall device can be further improved.

Further, the self-feedback circuit 40 consisting of the p-MOS 41 and the n-MOS 42 has a small circuit area, whereby the same has such an advantage that upsizing of the semiconductor chip 2 (the semiconductor device 1) can be avoided. The self-feedback circuit 40 also has such an advantage that current consumption is small.

In the aforementioned embodiment, the source of the p-MOS is connected to the high-voltage power source VDD, the source of the n-MOS is connected to the ground GND and the drain of the p-MOS and the drain of the n-MOS are connected with each other in the p-MOS and the n-MOS serially connected with each other between the high-voltage power source VDD and the ground GND. Alternatively, the drain of the n-MOS may be connected to the high-voltage power source VDD, the drain of the p-MOS may be connected to the ground GND and the source of the n-MOS and the source of the p-MOS may be connected with each other in the p-MOS and the n-MOS serially connected with each other between the high-voltage power source VDD and the ground GND.

While the structure having the PDP scan driver circuit 10 has been employed as an example, the present invention can be widely applied to a semiconductor device having an IC for Automotive Electronics or a motor driver IC.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2007-105213 filed with the Japan Patent Office on Apr. 12, 2007, the disclosure of which is incorporated herein by reference.

1. A semiconductor device comprising:
a semiconductor substrate;
a p-channel MOS transistor formed on a surface layer portion of the semiconductor substrate;
an n-channel MOS transistor formed on the surface layer portion of the semiconductor substrate and serially connected with the p-channel MOS transistor between a power source and a ground; and
a substrate potential control circuit for controlling the potential of the back surface of the semiconductor substrate to an intermediate potential higher than the ground potential and lower than the potential of the power source.

2. The semiconductor device according to claim 1, wherein
the source of the p-channel MOS transistor is connected to the power source,
the source of the n-channel MOS transistor is connected to the ground, and
the drain of the p-channel MOS transistor and the drain of the n-channel MOS transistor are connected with each other.

3. The semiconductor device according to claim 1, wherein
the substrate potential control circuit includes:
a resistor having an end connected to the power source and another end connected to the ground, and
a connecting wire for electrically connecting an intermediate portion of the resistor and the back surface of the semiconductor substrate with each other.

4. The semiconductor device according to claim 1, wherein
the substrate potential control circuit includes:
a self-feedback p-channel MOS transistor formed on the semiconductor substrate with a gate and a source connected to the power source and a drain connected to a voltage output terminal,
a self-feedback n-channel MOS transistor formed on the semiconductor substrate with a gate and a source connected to the ground and a drain connected to the voltage output terminal, and
a connecting wire for electrically connecting the voltage output terminal and the back surface of the semiconductor substrate with each other.
